(19) United States
(12) Patent Application Publication
(10) Pub. No.: US 2026/0133272 A1
(43) Pub. Date: May 14, 2026

(54) Resolution-Enhanced MR Image Reconstruction with K-Space Boundary Correction

(71) Applicant: Siemens Healthineers AG, Forchheim (DE)

(72) Inventors: Mario Zeller, Erlangen (DE); Christian Meixner, Erlangen (DE)

(73) Assignee: Siemens Healthineers AG, Forchheim (DE)

(21) Appl. No.: 19/388,063

(22) Filed: Nov. 13, 2025

(30) Foreign Application Priority Data
Nov. 14, 2024 (DE) 10 2024 210 934.7

(51) Int. Cl. G01R 33/48; G01R 33/56; G01R 33/561

(52) U.S. Cl. CPC G01R 33/4818; G01R 33/5602; G01R 33/5608; G01R 33/561

(57) ABSTRACT

A computer-implemented method for processing magnetic resonance data recorded in k-space, sampled along a k-space trajectory, to enhance spatial resolution. The method includes: reconstructing a low-resolution basic image and applying a trained resolution-enhancing function to obtain a higher-resolution intermediate image; transforming the intermediate image into an intermediate k-space dataset; replacing portions of the intermediate k-space that correspond to originally sampled k-space positions with the actual recorded magnetic resonance data to form a target dataset; and reconstructing a higher-resolution target image from the target dataset. In a correcting procedure, edge height at one or more boundaries between the sampled k-space and an extension portion generated by the resolution enhancement is reduced, the edge height resulting from intensity weightings due to sampling time following radio frequency excitation, which are present in the sampled data but absent in the extension portion.

### TECHNICAL FIELD

The disclosure relates to a computer-implemented method for processing a magnetic resonance dataset, the magnetic resonance data of which is recorded in the k-space at different k-space positions, which are sampled along a k-space trajectory using a magnetic resonance sequence, with a magnetic resonance facility in a recording procedure, wherein, in order to enhance the spatial resolution of the magnetic resonance dataset in the image space
an, in particular, trained resolution enhancing function is applied to a low resolution basic image reconstructed from the magnetic resonance data in order to obtain a higher resolution intermediate image,
from the intermediate image, by way of a Fourier transform, an intermediate dataset in the k-space is determined,
the portions of the k-space in the intermediate dataset that are covered by the magnetic resonance data of the magnetic resonance dataset in the k-space are replaced by the magnetic resonance data to obtain a target dataset, and
a higher resolution target image is reconstructed and provided from the target dataset.

In addition, the disclosure relates to an image processing facility, a computer program, and an electronically readable data carrier.

### BACKGROUND

Magnetic resonance imaging is an established tool in medical technology. Since magnetic resonance imaging often involves relatively long recording durations, a variety of approaches have previously been proposed for reducing them, for example, in order to increase the patient throughput and/or to enable improved mapping of dynamic processes and/or to increase its robustness in relation to movement. For this purpose, firstly magnetic resonance sequences have been developed in order to be able to scan faster, which not only includes magnetic resonance sequences with an ultra-short echo time, but also those which use a plurality of readout modules, in each of which, for example, k-space lines can be read out following a common radio frequency excitation pulse of a corresponding excitation module. Such a sequence is also designated an echo train.

A known class of such magnetic resonance sequences is the turbo-spin-echo (TSE) sequences, which use the RARE (Rapid Acquisition with Relaxation Enhancement) technique. Herein, a series of refocusing coils, in particular, with a flip angle of 180°, are used, in order, following a radio frequency excitation pulse, for example, with a flip angle of 90°, to provide an echo train, the refocused echoes of which are measured in the corresponding readout modules. For the recording of different k-space lines, different phase encoding gradients are used for the echoes.

An example of a TSE sequence is a so-called SPACE (Sampling Perfection with Application optimized Contrast using different flip angle Evolution) sequence. This is used, in particular, for 3D imaging (3D SPACE). It is distinguished, inter alia, by long echo trains (for example, more than 100 echoes), a short echo spacing, at least partially reduced flip angles (for example, for avoiding tissue heating), and optimized, efficient k-space trajectories.

In all the recording methods, in particular, those with long echo trains, due to various causes, a weighting can result and thereby an implied filtration of the magnetic resonance data in the sampled k-space. In other words, deviations of the actual scan result from the magnetic resonance signal that is ideally to be measured (for example, only the nominal echo time and/or in a first echo following the radio frequency excitation pulse) can occur, caused by different effects occurring at different time points at which sampling takes place at a k-space position. Due to the T2/T2* decay, for example, later echoes in an echo train have a lower intensity than earlier echoes. A variation of the flip angle over the echo train in order to achieve a storage and regaining of the signal along the longitudinal magnetization also leads to a change in the intensities over time. Depending upon the recording parameters set, the k-space trajectory can also change (reordering), for example, in order to achieve a desired echo time. However, the k-space trajectory finally defines when a k-space position is sampled.

The aforementioned effects lead to the intensities often deviating strongly from one another at different sides and/or limits of the sampled k-space. Whereas with a so-called centric reordering in which, along the k-space trajectory, firstly the k-space center is sampled, after which, sampling takes place laterally therefrom, in alternating manner, the intensity differences tend to be smaller, a so-called linear reordering in a k-space direction in which the k-space positions are sampled temporally one after another in the k-space direction such that the k-space center is sampled at a central echo time point, leads to large intensity differences between the edges of the sampled k-space that lie opposite one another in the k-space direction. However, these differences do not affect the reconstruction of a magnetic resonance image in the image space in a relevant manner, in particular, by way of and/or comprising a Fourier transform, from a corresponding magnetic resonance dataset, since within the sampled k-space between adjacent k-space positions, potential jumps and/or edges in the intensity tend to be small.

A further possibility for saving recording time and still providing magnetic resonance images of high quality is the subsequent increase in the spatial resolution, known under the label “superresolution”. A lower spatial resolution means that a smaller proportion of the k-space is to be sampled around the k-space center in order to record a magnetic resonance dataset. A resolution enhancing function can then be applied to a basic image reconstructed from the magnetic resonance dataset in the image space in order to increase, for example, to double the spatial resolution from a first spatial resolution of the basic image to a second spatial resolution.

Resolution enhancing functions, in particular, superresolution functions are often trained by way of machine learning. For example, neural networks and/or comparable architectures of artificial intelligence can be used. Since the resolution enhancing functions operate in the image space, as a result of these, changes to the magnetic resonance data of the underlying magnetic resonance dataset can occur when the resolution is increased. If, for example, the spatial resolution is doubled, the filled k-space is twice as large as the sampled k-space, such that data can be changed in the originally sampled k-space center.

In order to ensure data consistency, current methods for increasing the resolution following the application of the corresponding resolution enhancing function also comprise a data consistency step that is intended to ensure that the high-resolution target image that is finally output matches the originally recorded k-space data of the magnetic resonance dataset. For this purpose, an intermediate image obtained as the output of the resolution enhancing function is transferred into the k-space by way of a Fourier transform, after which the corresponding intermediate data in the sampled central k-space that is covered by the magnetic resonance data is again overwritten, and therefore replaced, by the magnetic resonance data. This procedure is also designated “hard projection”. The intermediate data remains in the extension portion, extending the originally sampled k-space. From the target dataset determined in this way, the target image that is finally to be output can be reconstructed again by way of, or comprising, a Fourier transform.

Experiments have shown that during the performance of the data consistency step, so-called ringing artifacts can occur in the target images, indicating the presence of strong k-space edges in the target dataset. There is therefore a need for an improvement to the quality of magnetic resonance images that have been enhanced in their spatial resolution.

### SUMMARY

The disclosure is therefore based upon the object of providing a possibility for increasing the quality, in particular, for reducing artifacts of target images in which the spatial resolution of a magnetic resonance dataset has been enhanced by using a resolution enhancing function in the image space.

This object is achieved according to the disclosure by way of a computer-implemented method, an image processing facility, a computer program, and an electronically readable data carrier as claimed in the independent claims. Advantageous developments are disclosed in the subclaims.

In a method of the type mentioned in the introduction, it is provided according to the disclosure that, in a correcting procedure, at least one edge height at at least one boundary between the sampled k-space and an extension portion of the k-space extending the originally sampled k-space by way of the resolution enhancement is at least reduced, said edge height occurring by way of intensity weightings in the magnetic resonance dataset due to the time point of the sampling of each k-space position following a radio frequency excitation pulse during the magnetic resonance sequence, wherein the intensity weightings are not present in the extension portion.

According to the disclosure, it has been established that due to the intensity variations occurring in the magnetic resonance dataset, as already described above, due to the weighting, dependent upon the time point, and which are not contained in the intermediate data of the intermediate dataset in the extension portion, strong k-space edges can occur at the boundaries of the sampled k-space region to the extension portion in the target dataset and these lead to the aforementioned ringing artifacts. It is therefore proposed at least to reduce the edge height between the magnetic resonance data in the sampled k-space and the k-space data added by way of the resolution enhancing function in the extension portion in the target dataset, or even to avoid the edges entirely, so that a “constant” and/or continuous progression over the boundary is produced. In this way, artifacts can be prevented, and target images of relatively high quality are provided.

Resolution enhancing functions operate in the image space and are thus, for example, image-to-image networks. Thus for the resolution enhancing function, the different intensity weighting is not visible in the sampled k-space. This does not, per se, initially present a problem that only occurs if, in the context of the data consistency step, transformation back into the k-space takes place. Therein, the added high-frequency image information is distributed symmetrically in the mutually symmetrical high frequency k-space regions of the extension portion, which means that a k-space weighting is not present. If the central sampled k-space region is now replaced by the originally recorded magnetic resonance data, which contains the k-space weighting, at the seam sites, i.e., the boundaries, potential intensity jumps, i.e., k-space edges, arise.

On the basis of this knowledge, the edge height in the k-space is reduced at at least one boundary between the sampled k-space and the extension portion, in particular, on at least one side of the at least substantially rectangular and/or cuboid-shaped sampled k-space that arises through the intensity weighting during recording, in order to lessen the negative effects arising from these k-space edges, or even to prevent them altogether.

The method described here is particularly suitable, in general, for all application cases in which echo trains with a plurality of readout modules are used following a radio frequency excitation pulse, wherein possibly radio frequency refocusing pulses are used before associated readout modules, the flip angles of which can also vary. As already described in the introduction, during such echo trains, a weighting can take place by way of the progressing T2/T2* decay and/or by way of flip angle variations, and an unfavorable distribution of the weighting can occur due to the k-space trajectory. However, the procedure described here is also usable for fast and/or ultrafast magnetic resonance sequences with ultrashort echo times, which use echo times that are, for example, shorter than 10 ms, since therein a correspondingly fast decay of the magnetic resonance signal also occurs along a single k-space line. An example of such a fast magnetic resonance sequence is the UTE (Ultrashort Echo Time) sequence.

In preferred exemplary embodiments, it can be provided that, following a common radio frequency excitation pulse, the magnetic resonance sequence comprises an echo train with a plurality of readout modules. For example, the magnetic resonance sequence can be a TSE sequence, preferably a SPACE sequence, in particular, a 3D-SPACE sequence.

In a particularly advantageous embodiment of the present disclosure, it is proposed that
using a recording information item describing the recording procedure for each sampled k-space position and/or for a plurality of additional k-space positions defined in the extension portion, a weighting value of a weighting information item is determined that describes, on the basis of the actual, or, for the additional k-space positions, of a virtual time point of the sampling following a radio frequency excitation pulse during the magnetic resonance sequence, an expected deviation of the k-space value that occurs from an expected reference value for the magnetic resonance signal to be measured, and
the weighting information item is used for correction in the correcting procedure.

The reference and/or the reference value, which is not necessarily explicitly required, can relate, in the use of echo trains containing a plurality of echoes, for example, to a first echo. In particular, if deviations along a k-space line are also to be observed, the reference can be located at the nominal echo time (of the first echo). Naturally, however, other references are also conceivable in relation to which the difference in the intensity can be described by way of a weighting value.

Particularly preferably, the weighting information item is determined at least for the sampled k-space positions in the sampled k-space, so that the actually occurring weighting in the sampled k-space is determined and/or estimated. Herein, the weighting information item relates, in particular, to k-space positions sampled following an associated radio frequency excitation pulse, the resultant magnetic resonance signal of which is measured, wherein for different repetitions of such a sequence of excitation modules and at least one readout module, different weighting information items can also arise, for example, with relevant parameters varying between the repetitions. From the weighting information item for the sampled k-space, as will be described in greater detail, conclusions can be particularly advantageously drawn regarding where a correction is necessary (for example, where strong edges occur) and/or how a correction that leaves the magnetic resonance dataset unchanged, even in the target dataset, is conceivable. In other words, the weighting information item thus provides useful additional information in each case for a targeted correction, which, as far as possible, retains the matching with the original magnetic resonance dataset.

The weighting information item can be understood to be a k-space weighting matrix that contains, for each sampled k-space position and/or additional k-space position, a weighting value. For the sampled k-space, the weighting information item forms a k-space filter that is evoked by the different weightings of the respective k-space positions.

Herein, the weighting information item does not necessarily have to be determined resolved for all the relevant directions of the k-space which, for a two-dimensional recording, can be, for example, k_{y} (phase encoding direction) and kₓ (readout direction) and, for a three-dimensional recording, can be, for example, k_{y}, k_{z} (phase encoding directions) and kₓ (readout direction). In particular, it can be provided that in the recording of a plurality of k-space lines following an excitation pulse, a common weighting value is associated with each k-space line. This is based upon the assumption that, in the progression of the sampling of a single k-space line, the weighting changes only slightly, which applies, in particular, in the case of echo trains in which, for each echo, a k-space line can be read out, for example, a TSE sequence. In other words, in a two-dimensional recording, the weighting matrix would be one-dimensional (changing only in the k_{y}-direction), and in a three-dimensional recording, for example, 3D-SPACE, it would be two-dimensional (changing only in the k_{y} and k_{z}). Accordingly, the boundaries can then also only be defined along these directions.

However, as already indicated, application cases are also conceivable in which, during the recording of a k-space line, sufficient effects relating to the weighting values occur, for example, in the aforementioned UTE recordings, so that in this case, a resolution also in the readout direction (normally kₓ) is useful. Naturally, this can also be implemented, in principle, and therefore also for magnetic resonance sequences using echo trains.

Suitably, it can be provided that the recording information describes at least one sequence information item regarding the sampling of the sampled k-space positions, in particular, the k-space trajectory and/or recording time points at the respective k-space positions, and/or a relaxation information item relating to T2 decay and/or a flip angle information item relating to the progression of the flip angle applied over the magnetic resonance sequence. Whereas the sequence information item that can have arisen through a reordering shows when a k-space position has been sampled, the relaxation information item and the flip angle information item directly or indirectly describe the temporal sequence of effects that have an influence on the weighting arising, so that the summary enables weighting values to be determined for corresponding recording time points and/or k-space positions.

Specifically, the sequence information item and/or the flip angle information item can be determined from a control information item used for carrying out the magnetic resonance sequence and/or retrospectively from a metainformation item associated with the magnetic resonance dataset. Dependent upon the available information sources, it is therefore firstly possible that the sequence information item and/or the flip angle information item is determined, for example, directly from a protocolling and/or for carrying out the magnetic resonance frequency and/or a recording protocol comprising it, specifically control information. It is, however, conceivable, in particular, in relation to the sequence information item, also to determine it retrospectively if corresponding metainformation, in particular, recording time points, is associated with the magnetic resonance dataset. As far as the relaxation information is concerned, it can be determined from a recording region information item describing the recorded recording region, in particular, its material structure. For example, relaxation times, in particular, T2 and/or T2* relaxation times, can be associated with different recording regions of a human and/or different material structures and/or material compositions, and can serve as the basis for calculating, modelling, and/or simulation of the corresponding decay. For example, for recordings of the head of a patient, a T2 relaxation time of 200 ms and, for recordings in the abdomen of a patient, a T2 relaxation time of 500 ms can be assumed. It is, however, also possible to determine the relaxation information at least partially on the basis of a magnetic resonance measurement forming, in particular, part of the magnetic resonance sequence. Comparable measurement values describing the T2 and/or T2* decay in their temporal sequence can be determined, for example, by way of dedicated scans, but preferably by way of scans that are, in any case, carried out, in which, for example, no phase encoding gradients and/or readout gradients are used. For example, in a TSE sequence, it is known before the actual scan to carry out a phase correction scan to correct eddy current effects. This recording comprises a complete echo train and takes place without phase encoding. The phase data of such a phase correction scan is made use of for the correction, whereas the magnitude data can be used in order to determine a progression profile for relaxation.

In general, it can be provided that the weighting information item is determined at least partially by means of a simulation and/or a modeling. For example, it is conceivable to carry out a Bloch simulation and/or to use an extended phase graph formalism. A modelling of decay processes can take place, for example, exponentially. For example, herein, the aforementioned relaxation times associated with recording regions and/or material structures can be used.

In general, at this point, it should be noted that for additional k-space positions, for example, weighting information items can be determined by way of simulation, modelling and/or calculation if a sampling pattern, in particular, the k-space trajectory, described by the sequence information item, in particular, the k-space trajectory is continued outside the sampled k-space. If, for example, a linear reordering is used, this can be “extended logically” to both sides in the corresponding direction. This applies similarly for other reordering schemes. Then it is possible also in exemplary embodiments, in particular, to determine the weighting information item only for the extension portion of the k-space and to use it for correction, although it is preferred, for improved assessment of the situation, also at least additionally to determine the weighting information item for the sampled k-space so that, for example, the occurrence of excessively strong k-space edges can be established particularly on the basis of such a continuation of the sampling pattern and/or reordering scheme, which is conceivable in some sampling patterns and, for example, a further adaptation can take place.

In principle, within the context of the present disclosure, two approaches to the specific realization of the correcting procedure are suitably conceivable. In a preferred first specific embodiment, it can herein be provided, for correcting the target dataset in the correcting procedure, that
the weighting information item in the extension portion of the k-space in the target dataset is continuously, in particular, constantly continued in relation to a function describing the progression in the sampled k-space, and/or is determined for this, and
the weighting information item for weighting the k-space values of the target dataset is applied in the extension portion.

Therein, it is generally preferred to continue the weighting information item into the extension portion since, in this way, the “constant” transition with the lowest possible edge height can actually be ensured, which, as shown above, is not directly possible at least if the weighting information item is determined directly only for the extension portion (for example, by continuation of a sampling pattern and/or a k-space trajectory). If the weighting information item is determined, for example, as a weighting matrix and if, for the description of the intermediate data in the k-space, additional k-space positions are used for which a weighting value can then be assigned by way of the continuation and/or generally the determination, the application of the weighting information item can be understood as a multiplication of the weighting matrix with k-space values in the extension portion. In principle, however, other specific implementation possibilities for applying the weighting determined for the extension portion to the k-space values are also conceivable.

In this first embodiment, particularly advantageously, no modification of the magnetic resonance data of the magnetic resonance dataset in the originally sampled k-space is necessary so that the consistency is maintained completely; however, a significant improvement in the image quality, in particular, the avoidance of artifacts, and an increase in image sharpness is achieved.

Specifically, it can be provided that the continuation and/or determination of the weighting information item for the extension portion takes place through extrapolation and/or continuation of a weighting pattern formed within the sampled k-space. For the extrapolation, the progression within the sampled k-space can be described, for example, by way of a function that is constantly continued in the extension portion, that is, extrapolated. Other possibilities for continuing the weighting pattern, for example, a cyclical enhancement while taking account of an envelope or similar, are also conceivable.

In a second, specific embodiment for carrying out the correcting procedure, it can be provided that for correcting the target dataset at at least one boundary from the originally sampled k-space to the extension portion of the k-space, in particular, at at least one side of the sampled k-space, the progression of the k-space values in an environment around the edge for reducing a k-space edge, in particular, for producing a constant progression of a function describing the progression of the k-space values, is filtered. Therefore, a conventional filter can be used in order to reduce the edge height at boundaries between the sampled k-space and the extension portion. In principle, however, it is conceivable to carry this out at all the boundaries, for example, at all sides of the sampled k-space, although no weighting information item would then be needed, however-independently of the actual necessity-an influencing and alteration of the magnetic resonance data would then occur in the sampled k-space, which leads to an, even if only slight, reduction of the constancy that is to be achieved by way of the data consistency step.

Therefore, a particularly advantageous development of this second embodiment provides that the at least one boundary where filtering takes place is selected dependent upon the weighting information item determined as described above, as the at least one boundary with the greatest edge height. Therefore, the edges with the greatest jumps are determined. It should be noted herein that, for this application scenario, it can be sufficient to determine the weighting information item, in particular, the weighting matrix, only very roughly, in order to be able to assess how large the asymmetry is between the respective sides. In other words, the weighting matrix can be determined in the sampled k-space in a coarser resolution than the resolution provided by way of the sampled k-space positions. The selection of boundaries at which relatively strong signal jumps are present leads to the originally recorded magnetic resonance data being changed less, and therefore, a better consistency is the result. Negative effects, such as, for example, artifacts, are, however, reduced and/or suppressed.

In the example of the linear reordering set out above, for example, if for k-space lines, for a two-dimensional sampling, a common weighting value is assumed, a view of the k-space direction in which the k-space lines are recorded in succession, with slowly falling weighting, is sufficient. Then, on the basis of the at least substantially exponentially progressing signal weighting (due, in particular, to the T2 decay), it is to be assumed that on the side and/or boundary that is sampled first in the recording, a larger edge height comes about. It is thus sufficient at the boundary at which the first k-space line has been recorded to carry out the filtration, while the other boundary can remain unaltered. In the event of a three-dimensional sampling, for example, two boundaries (from four) can be selected.

In general, it is therefore conceivable to sort the boundaries, in particular, sides of the k-space initially according to their edge height in accordance with the weighting information item, after which the n strongest edges are selected for filtration. Depending upon the dimensionality of the weighting information item, n can be selected to be, for example, one to four. In addition or alternatively, it is also possible to use a selection condition that is met by an edge height exceeding a threshold value, wherein only the boundaries meeting the selection condition can be selected.

As previously mentioned, a conventional filter can be used for filtration at a selected boundary. For example, a Fermi filter or a linear filter can be used for filtration.

Besides the method, the present disclosure also relates to an image processing facility comprising a control facility with at least one processor and at least one storage means, having:
a first interface for receiving a magnetic resonance dataset, the magnetic resonance data of which is recorded in the k-space at different k-space positions, said data being sampled along a k-space trajectory using a magnetic resonance sequence, with a magnetic resonance facility in a recording procedure,
a reconstructing unit for reconstructing a basic image in a first lower spatial resolution from the magnetic resonance dataset,
a resolution enhancing unit for increasing the spatial resolution of the magnetic resonance dataset in the image space by applying a, in particular, trained resolution enhancing function to the basic image in order to obtain an intermediate image of a second higher spatial resolution,
a consistency unit that is configured for determining an intermediate dataset in the k-space from the intermediate image by way of a Fourier transform and for replacing the portions of the k-space in the intermediate dataset that are covered by the magnetic resonance data of the magnetic resonance dataset in the k-space by the magnetic resonance data to obtain a target dataset, wherein the reconstructing unit is configured for reconstructing a target image of the second spatial resolution from the target dataset,
a correcting unit for reducing, in a correcting procedure, at least one edge height at at least one boundary between the sampled k-space and an extension portion of the k-space extending the originally sampled k-space by way of the resolution enhancement, said edge height occurring by way of intensity weightings in the magnetic resonance dataset due to the time point of the sampling of each k-space position following a radio frequency excitation pulse during the magnetic resonance sequence, wherein the intensity weightings are not present in the extension portion, and
a second interface for providing the target image.

All the aspects relating to the method according to the disclosure can be transferred similarly to the image processing facility according to the disclosure and vice versa, so that the advantages mentioned above can therefore also be obtained with the image processing facility. By way of hardware and/or software, functional units are formed in order to perform steps of the method according to the disclosure. Apart from the aforementioned functional units, further functional units for advantageous developments of the method according to the disclosure can naturally also be provided, for example, a determining unit for determining the weighting information item.

The image processing facility can be part of a magnetic resonance facility so that, therein, a direct image processing for resolution enhancement with target images of high quality can take place, and, in particular, the necessary information for determining the weighting information item directly is already available.

A computer program according to the disclosure is able to be loaded directly into a memory storage means of a control facility of an image processing facility and has program means that are configured such that when the computer program is executed on the control facility, said control facility is caused to carry out the steps of a method according to the disclosure. The computer program can be stored on an electronically readable data carrier according to the disclosure which therefore has control information stored thereon which comprises at least a computer program according to the disclosure and is configured such that, on use of the data carrier in a control facility of an image processing facility, said control facility is configured to carry out a method according to the disclosure. The data carrier can be, in particular, a non-transient data carrier, for example, a CD-ROM.

### BRIEF DESCRIPTION OF THE DRAWINGS

Further advantages and details of the present disclosure are disclosed in the exemplary aspects described below, making reference to the drawings. In the drawings:

FIG. 1 shows a flow diagram of a first exemplary aspect of the method according to the disclosure;

FIG. 2 shows an exemplary progression of weighting values of the k-space;

FIG. 3 shows a progression of k-space values following performance of a data consistency step;

FIG. 4 shows the progression of k-space values following a correction using the weighting values of FIG. 2;

FIG. 5 shows a flow diagram of a second exemplary aspect of the method according to the disclosure; and

FIG. 6 shows a sketch of the principle of an image processing facility according to the disclosure.

### DETAILED DESCRIPTION

Exemplary aspects of the method according to the disclosure are described below in relation mainly to a magnetic resonance sequence in which a plurality of echoes in an echo train follow a radio frequency excitation pulse, wherein, furthermore, for the sake of simplicity, a two-dimensional sampling is assumed. For example, the magnetic resonance sequence can be a TSE sequence. However, the description above can similarly also be transferred to other magnetic resonance sequences, in particular, those in which relatively strong weightings occur along a single k-space line and/or, in general, a single echo.

For the exemplary aspects described here, a magnetic resonance dataset is already available for which, by means of the magnetic resonance frequency, magnetic resonance data has been recorded at different sampled k-space positions within a sampled k-space. On the basis of different effects already described in detail, in particular, relaxation and, if used, flip angle variations, for the different recording time points that result from the k-space trajectory (which gives the recording sequence for the k-space positions), different weightings of the k-space values of the magnetic resonance dataset arise.

For the magnetic resonance dataset, a target image with enhanced spatial resolution is to be determined which should be as consistent as possible with the original magnetic resonance dataset and have the highest possible quality. Thus, a correction takes place for excessively strong k-space edges arising due to the weighting, for which purpose, in the following, two aspects of the correcting procedure, each embedded in the resolution enhancement procedure, will be described.

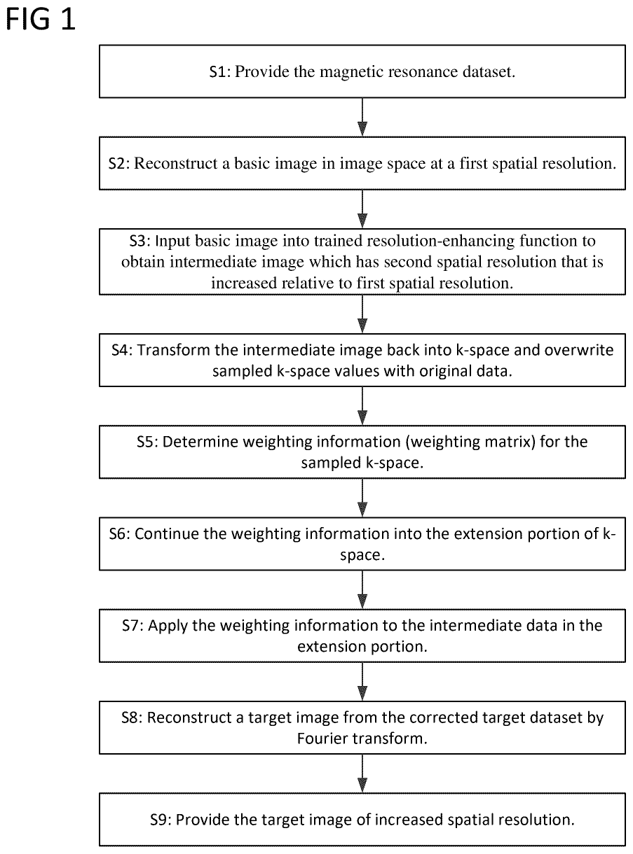

FIG. 1 shows a flow diagram of a first exemplary aspect of the method according to the disclosure in a first aspect. Therein, in a step S1, the magnetic resonance dataset is provided. In a step S2, a basic image is reconstructed from the magnetic resonance dataset in the image space (spatial domain), in particular, by way of and/or comprising a Fourier transform. Since only the sampled k-space is used, the basic image has a first, relatively low spatial resolution.

As is known in principle, the basic image serves, in a step S3, as input data of, in this case, a trained resolution enhancing function, for example, a superresolution function which outputs as output data an intermediate image which has a second spatial resolution that is increased relative to the first spatial resolution. For example, the spatial resolution can be doubled.

In order to ensure the data consistency, the intermediate image is transformed back in a data consistency step S4 into the k-space where, in order to obtain a target dataset in the central, sampled k-space where k-space values of the magnetic resonance dataset are present, the corresponding k-space values of the intermediate dataset are overwritten and are therefore replaced by the magnetic resonance data. In the added extension portion surrounding the sampled k-space, due to the increase in the spatial resolution, the intermediate data remains.

In the context of this replacement, on the basis of the weighting described above and/or the implicit filtration of the magnetic resonance dataset in the k-space at the boundaries between the sampled k-space and the extension portion where a weighting of this type is not present, but rather a symmetrical distribution of the high frequency information items is provided, a k-space edge can occur with an edge height which can lead to artifacts and/or image quality losses. Therefore, a correcting procedure takes place for which firstly in a step S5, a weighting information item is determined for the sampled k-space which comprises weighting values for each sampled k-space position. Therefore, the weighting information item can also be understood as a weighting matrix.

The weighting matrix is determined from recording information items via the recording procedure of the magnetic resonance dataset, which, in the present case, comprises a sequence information item, in particular, the k-space trajectory used, a relaxation information item regarding the T2/T2* relaxation, and a flip angle information item. The sequence information item and the flip angle information item can be derived, for example, directly from information regarding the magnetic resonance sequence, for example, control information items and/or metainformation items associated with the magnetic resonance dataset; the relaxation information item can be retrieved, for example, on the basis of the recording region and/or the material structure in the recording region as at least one corresponding relaxation time, from a database and/or can be the result of a scan. For example, in the TSE sequences cited as an example, before the actual scan, a phase correction scan is carried out without the use of phase encoding gradients, the measured magnitude values of which describe the T2/T2* decay. Even without phase encoding gradients and/or readout gradients at individual time points, existing scan portions and/or echoes can be taken into account as relaxation information, for example, by interpolation of the corresponding progression. Dedicated scans can also be provided.

In the determination of the weighting information item, at least one simulation and/or a modelling and/or a calculation can be utilized. For example, given the presence of relaxation times, an exponential decay can be assumed as the modelling. With regard, in particular, to the effect of flip angle variations and/or other relatively complex interactions, a Bloch simulation can also be used, and/or an extended phase graph formalism can be used.

In the present exemplary aspect, it is assumed that during a single echo, in particular the readout of a single k-space line, the change of the weighting is too low to be relevant. Therefore, along a k-space line, only a single common weighting value is determined for all the k-space positions of this k-space line. In other words, the weighting information item is not determined or resolved in the kₓ-direction.

The weighting information item determined in this way is continued into the extension portion in a step S6, in particular, by way of extrapolation and/or continuation of a weighting pattern. This necessarily leads to as “constant” a transition as possible at the boundary between the sampled k-space and the extension portion. Therefore, weighting values are available in the extension portion for additional k-space positions provided in the corresponding resolution. This weighting information item of the extension portion is then applied in a step S7 to the k-space values in the extension portion which have remained as the intermediate data, so that, on the basis of the constant continuation of the weighting information item into the extension portion, minimal or at least reduced edge heights arise at the boundaries between the sampled k-space and the extension portion. For the sake of consistency, the originally recorded magnetic resonance data in the sampled k-space must not be changed.

A target image of the second spatial resolution reconstructed in step S8 by Fourier transform from the thus corrected and determined target dataset that is provided in step S9 has a high quality that is not influenced by signal jumps in the k-space.

It should be noted that steps S5 and S6 can be carried out at any desired time points before step S7, for example, even before the data consistency step S4.

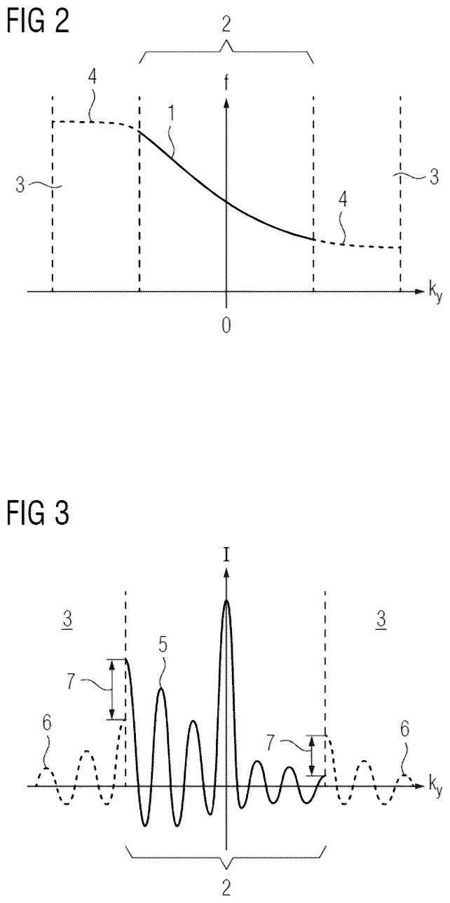

FIGS. 2 to 4 illustrate this procedure using the example of the k_{y}-direction (phase encoding direction), starting from a common weighting value for k-space lines and a two-dimensional recording technology. FIG. 2 shows the progression 1 of the weighting values f in the sampled k-space 2 around the k-space center. It is evident that there is a significant asymmetry, for example, due to a linear reordering in the k_{y}-direction. The weighting falls from a high value at negative k_{y}-values to a low value at positive k_{y}-values. The graph of FIG. 2 also shows the extension portion 3 in which the progression 1 of the weighting values is constantly continued according to step S6 by extrapolation, as per the progressions 4.

FIG. 3 shows the effect of the replacement of the intermediate data in the sampled k-space 2 by the original magnetic resonance data (progression 5 of the k-space values and/or intensities I). Evidently, in addition to the further progression 6 of the intermediate data present in the extension portion 3, k-space edges of an appreciable edge height 7 are formed.

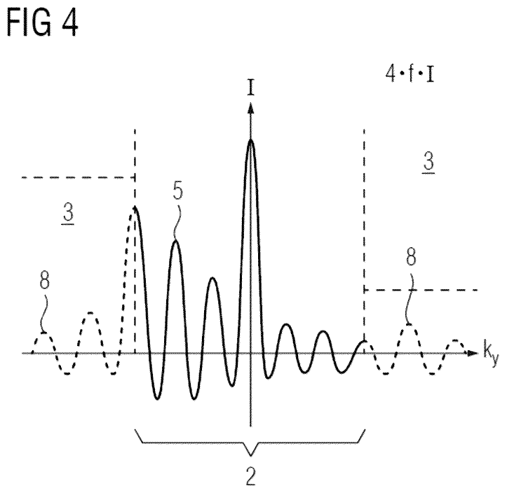

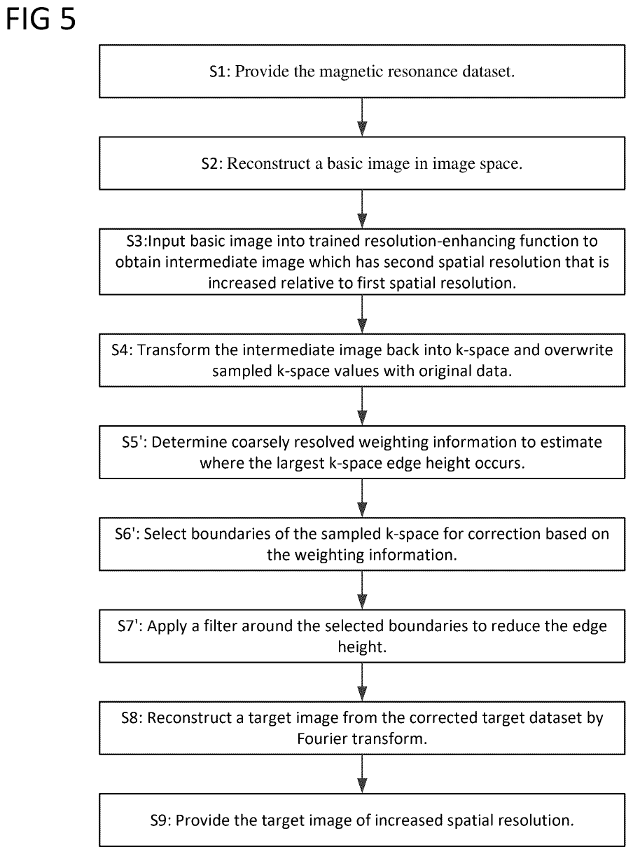

If the correction is now carried out, that is, the weighting values (progression 4) are applied to the progression 6 in the extension portion 3, in particular, through multiplication of the weighting value by the k-space value at each additional k-space position, the progression 8 continuing in the extension portion 3 from the progression 5 constantly, that is, without a jump arises, as shown in the continuous representation in FIG. 4.

FIG. 5 shows a second exemplary aspect of the method according to the disclosure in a second aspect, such that the correcting procedure is modified. Whereas steps S1 to S4 are unchanged, in a step S5′, the weighting information item is determined more coarsely resolved than in step S5 since it is only intended to allow an estimate therefor at which at least one boundary between the sampled k-space 2 and the extension portion 3 the greatest jump and therefore the highest edge height is present. Therefore, this weighting information item is used in step S6′ in order to select boundaries, in particular, sides of the sampled k-space 2 at which a correction is to take place. For example, in the case of the resolution along just the k_{y}-direction, one of two relevant edges can be selected, for example, the left edge, since, due to the at least substantially exponentially progressing weighting, the stronger jump is expected there. If resolution into two directions has taken place, two of four (or even six) boundaries/sides can be selected. Alternatively or additionally, in step S6′ a selection condition can be utilized which checks, for example, whether the expected edge height is greater than a threshold value.

In a step S7′, the correction takes place in that a filter, here a Fermi filter, is applied to an environment around the selected boundaries, in order to reduce the edge height.

Steps S8 and S9 then correspond again to the first aspect.

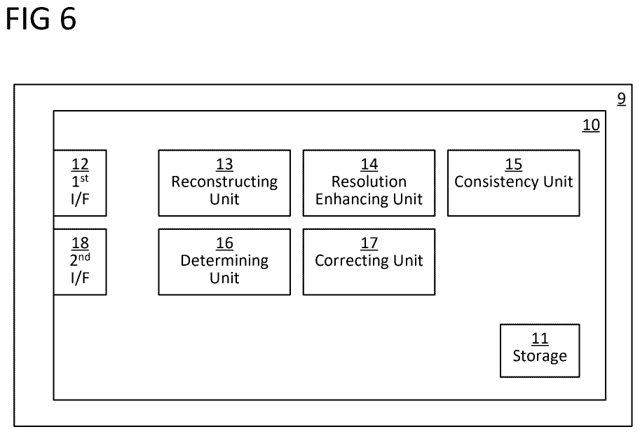

Finally, FIG. 6 shows a sketch of the principle of an image processing facility 9 according to the disclosure. This has a control facility 10 (computing facility) with at least one processor and a storage means 11 the functional structure of which is also shown in FIG. 6. Via a first interface 12, the control facility 10 can receive the magnetic resonance dataset according to step S1. In a reconstructing unit 13, magnetic resonance images can be reconstructed from the corresponding k-space data, in particular, according to steps S2 and S8. The reconstructing unit 13 can also be utilized in the data consistency step S4 in order to transform the intermediate image into the k-space and back.

A resolution enhancing unit 14 is configured to apply the, in particular, trained resolution enhancing function according to step S3 to the reconstructed basic image in order to obtain the intermediate image. The consistency unit 15 is configured for carrying out the data consistency step S4.

In order to implement the correcting procedure, the control unit 10 now initially has a determining unit 16 for determining the weighting information item according to step S5 and/or S5′. A correcting unit 17 is provided for the relevant execution of steps S6 and S7 and/or S6′ and S7′ and therefore for reducing the edge height at at least one boundary between the sampled k-space 2 and the extension portion 3.

By means of a second interface 18, the target image can be provided according to step S9.

Independent of the grammatical term usage, individuals with male, female or other gender identities are included within the term.

1. A computer-implemented method for processing a magnetic resonance dataset, the magnetic resonance data of which is recorded in k-space at different k-space positions which are sampled along a k-space trajectory using a magnetic resonance sequence, with a magnetic resonance apparatus in a recording procedure, wherein in order to enhance a spatial resolution of the magnetic resonance dataset in the image space, the method comprises:
applying a trained resolution enhancing function to a low resolution basic image reconstructed from the magnetic resonance data in order to obtain a higher resolution intermediate image;
determining, from the intermediate image by way of a Fourier transform, an intermediate dataset in the k-space;
in order to obtain a target dataset, replacing the portions of the k-space in the intermediate dataset that are covered by the magnetic resonance data of the magnetic resonance dataset in the k-space by the magnetic resonance data; and
reconstructing and providing a higher resolution target image from the target dataset,
wherein in a correcting procedure, at least one edge height at at least one boundary between the sampled k-space and an extension portion of the k-space extending the originally sampled k-space by way of the resolution enhancement is reduced, the edge height occurring by way of intensity weightings in the magnetic resonance dataset due to the time point of the sampling of each k-space position following a radio frequency excitation pulse during the magnetic resonance sequence, wherein the intensity weightings are not present in the extension portion.

2. The method as claimed in claim 1, further comprising:
using a recording information item describing the recording procedure for each sampled k-space position and/or for a plurality of additional k-space positions defined in the extension portion, determining a weighting value of a weighting information item that describes, based on the actual, or, for the additional k-space positions, of a virtual time point of the sampling following a radio frequency excitation pulse during the magnetic resonance sequence, an expected deviation of the k-space value that occurs from an expected reference value for the magnetic resonance signal to be measured; and
using the weighting information item for correction in the correcting procedure.

3. The method as claimed in claim 2, wherein in the recording of a plurality of k-space lines following an excitation pulse, a common weighting value is associated with each k-space line.

4. The method as claimed in claim 2, wherein the recording information describes at least one sequence information item regarding the sampling of the sampled k-space positions, in particular, the k-space trajectory and/or recording time points at the respective k-space positions, and/or a relaxation information item relating to T2 decay and/or a flip angle information item relating to the progression of the flip angle applied over the magnetic resonance sequence.

5. The method according to claim 4, wherein the sequence information item and/or the flip angle information item can be determined from a control information item used for carrying out the magnetic resonance sequence and/or retrospectively from a metainformation item associated with the magnetic resonance dataset, and/or in that the relaxation information item is determined from a recording region information item describing the recorded recording region, in particular, its material structure and/or on the basis of a magnetic resonance measurement forming, in particular, part of the magnetic resonance sequence.

6. The method as claimed in claim 2, wherein the weighting information item is determined at least partially using a simulation and/or a modelling.

7. The method as claimed in claim 2, wherein for correcting the target dataset:
the weighting information item in the extension portion of the k-space in the target dataset is continuously continued in relation to a function describing the progression in the sampled k-space or is determined for this, and
the weighting information item is applied for weighting the k-space values of the target dataset in the extension portion.

8. The method as claimed in claim 7, wherein the continuation or determination of the weighting information item for the extension portion takes place through extrapolation or continuation of a weighting pattern formed within the sampled k-space.

9. The method as claimed in claim 1, wherein for correcting the target dataset at at least one boundary from the originally sampled k-space to the extension portion of the k-space, the progression of the k-space values in an environment around the edge for reducing a k-space edge is filtered.

10. The method as claimed in claim 9, wherein a weighting information item is determined that describes, based on the actual, or, for additional k-space positions, a virtual time point of the sampling following a radio frequency excitation pulse during the magnetic resonance sequence, an expected deviation of the k-space value from an expected reference value for the magnetic resonance signal to be measured,
and the weighting information item is used for correction in the correcting procedure, and wherein the at least one boundary at which filtering takes place is selected dependent upon this weighting information item as the at least one boundary having the large edge height.

11. The method as claimed in claim 9, wherein for filtration, a Fermi filter or a linear filter is used.

12. The method as claimed in claim 1, wherein following a common radio frequency excitation pulse, the magnetic resonance sequence comprises an echo train with a plurality of readout modules.

13. An image processing apparatus having a control apparatus with at least one processor and at least one storage device, comprising:
a first interface configured to receive a magnetic resonance dataset, the magnetic resonance data of which is recorded in k-space at different k-space positions, the data being sampled along a k-space trajectory using a magnetic resonance sequence, with a magnetic resonance apparatus in a recording procedure;
a reconstructing unit configured to reconstruct a basic image of a first lower spatial resolution from the magnetic resonance dataset;
a resolution enhancing unit configured to increase the spatial resolution of the magnetic resonance dataset in image space by applying a trained resolution enhancing function to the basic image to obtain an intermediate image of a second higher spatial resolution;
a consistency unit configured to determine an intermediate dataset in the k-space from the intermediate image by way of a Fourier transform and to replace the portions of the k-space in the intermediate dataset that are covered by the magnetic resonance data of the magnetic resonance dataset in the k-space by the magnetic resonance data to obtain a target dataset, wherein the reconstructing unit is configured to reconstruct a target image of the second spatial resolution from the target dataset;
a correcting unit configured to reduce, in a correcting procedure, at least one edge height at at least one boundary between the sampled k-space and an extension portion of the k-space extending the originally sampled k-space by way of the resolution enhancement, the edge height occurring by way of intensity weightings in the magnetic resonance dataset due to the time point of the sampling of each k-space position following a radio frequency excitation pulse during the magnetic resonance sequence, wherein the intensity weightings are not present in the extension portion; and
a second interface configured to provide the target image.

14. A non-transitory electronically readable data carrier on which a computer program is stored and which, when it is executed on a control apparatus of an image processing apparatus, causes the control apparatus to carry out the steps of a method as claimed in claim 1.
